(19) United States
(12) Patent Application Publication
(10) Pub. No.: US 2026/0290747 A1
(43) Pub. Date: Sep. 24, 2026

(54) PARTICLE BEAM MICROSCOPE

(71) Applicant: Carl Zeiss Microscopy GmbH, Jena (DE)

(72) Inventor: Bjoern GAMM, Königsbronn (DE)

(21) Appl. No.: 19/575,490

(22) Filed: Mar. 23, 2026

(30) Foreign Application Priority Data
Mar. 24, 2025 (DE) 10 2025 111 316.5

(51) Int. Cl. H01J 37/26; H01J 37/14; H01J 37/21; H01J 37/244

(52) U.S. Cl. CPC H01J 37/265; H01J 37/14; H01J 37/21; H01J 37/244; H01J 2237/04735; H01J 2237/04922; H01J 2237/24507

(57) ABSTRACT

A particle beam microscope comprises a particle beam column and a controller. The particle beam column comprises: a particle source for providing a particle beam; an acceleration electrode for accelerating particles in the particle beam; an objective lens for focusing the particle beam on a work region; a first detector configured to output a first detection signal based on particles incident on a first detection area, with the first detection area being arranged within the particle beam column between the acceleration electrode and the objective lens and at least partially surrounding a first clearance traversed by the particle beam when the particle beam column is in operation; a second detector configured to output a second detection signal based on particles incident on a second detection area, with the second detection area being arranged within the particle beam column between the acceleration electrode.

### CROSS-REFERENCE TO RELATED APPLICATION

This application claims benefit under 35 U.S.C. § 119 to German Application No. 10 2025 111 316.5, filed Mar. 24, 2025. The entire disclosure of this application is incorporated by reference herein.

### FIELD

The present disclosure relates to a particle beam microscope. For example, the particle beam microscope is an electron beam microscope, a scanning electron microscope, an ion beam microscope or a scanning ion microscope.

### BACKGROUND

Known scanning electron microscopes raster-scan an electron beam over a sample in order to acquire images of the sample. To acquire such images, a detector detects interaction products from an interaction of the electron beam with the sample. The detector outputs a detection signal based on the detections of the interaction products. The detection signal is used by a controller to generate an image of the sample.

An example of such a detector is a detector primarily provided for the detection of secondary electrons (“secondary electron detector”). The secondary electron detector can be arranged in the interior of the electron beam column of a scanning electron microscope, between an objective lens of the electron beam column and an electron source of the electron beam column. The secondary electron detector comprises a detection area sensitive to electrons. The detection area of the secondary electron detector has an opening through which the sample-bound particle beam passes. The secondary electron detector detects those interaction products originating from the sample that are incident on the detection area of the secondary electron detector.

A further example of such a detector is a detector primarily provided for the detection of substantially elastically scattered electrons (“backscattered electron detector”). The backscattered electron detector can be arranged in the interior of the electron beam column, between the detection area of the secondary electron detector and the electron source. The backscattered electron detector comprises a detection area sensitive to electrons. The detection area of the backscattered electron detector also has an opening through which the sample-bound particle beam passes. The backscattered electron detector detects those interaction products originating from the sample that pass through the opening in the detection area of the secondary electron detector and are subsequently incident on the detection area of the backscattered electron detector.

With this detector arrangement, some of the secondary electrons can pass through the opening in the detection area of the secondary electron detector and therefore would not detected by the secondary electron detector. Secondary electrons that pass through the opening in the detection area of the secondary electron detector and are incident on the detection area of the backscattered electron detector can be detected by the backscattered electron detector and may in the process be incorrectly classified as backscattered electrons. Backscattered electrons that pass through both the opening in the detection area of the secondary electron detector and the opening in the detection area of the backscattered electron detector are not detected using this detector arrangement, which may lead to a weak detection signal of the backscattered electron detector.

### SUMMARY

The present disclosure seeks to provide a particle beam microscope that allows for better backscattered electron detection.

One aspect of the disclosure relates to a particle beam microscope comprising a particle beam column and a controller. The particle beam column comprises: a particle source configured to provide charged particles of a particle beam; an acceleration electrode configured to accelerate the particles in the particle beam; an objective lens configured to focus the particle beam on a work region outside the particle beam column; a first detector configured to output a first detection signal based on particles incident on a first detection area, with the first detection area being arranged within the particle beam column between the acceleration electrode and the objective lens and at least partially surrounding a first clearance traversed by the particle beam when the particle beam column is in operation; a second detector configured to output a second detection signal based on particles incident on a second detection area, with the second detection area being arranged within the particle beam column between the acceleration electrode and the first detection area and at least partially surrounding a second clearance traversed by the particle beam when the particle beam column is in operation; and an auxiliary lens configured to generate a magnetic field for focusing particles emanating from the work region and passing through the first clearance.

For example, the particle beam column is an electron beam column, wherein the particle beam is an electron beam, and the particles in the particle beam are electrons. Alternatively, the particle beam column is an ion beam column, wherein the particle beam is an ion beam, and the particles in the particle beam are ions.

A sample is arranged in the work region of the particle beam column when the particle beam microscope is used. The particle beam column generates the particle beam and directs the particle beam at the sample arranged in the work region, whereby interaction products are created. Depending on the type of particle beam column, the interaction products are e.g. electrons or ions. In addition, other types of interaction products may be produced, for example light or X-ray radiation, but these are not given any consideration in this document on account of their neutral electric charge.

The interaction products can be roughly divided into two categories, specifically secondary particles and backscattered particles. Secondary particles are electrically charged particles whose emission energy is significantly lower than the landing energy of the particles from the particle beam. Backscattered particles are electrically charged particles whose emission energy is only slightly less than or equal to the landing energy of the particles from the particle beam. The landing energy denotes the kinetic energy of a particle in the particle beam upon incidence on the sample. The emission energy denotes the kinetic energy of an interaction product immediately after formation of the interaction product.

The secondary particles emanating from the sample or the work region are guided in the interior of the particle beam column by the effect of the objective lens and are incident there (in part) on the first detection area of the first detector. As a result, the first detector generates a detection signal that is based on those secondary particles that are incident on the first detection area.

The backscattered particles emanating from the sample or the work region are guided in the interior of the particle beam column by the effect of the objective lens and have a similar trajectory to the particle beam itself. For example, the backscattered particles pass through the first clearance and are subsequently focused by the effect of the auxiliary lens. Thus, the effect of the auxiliary lens is that the particles that emanate from the sample or the work region and pass through the first clearance are deflected laterally, i.e. transversely to a central axis of the particle beam column. As a result of this deflection, a large proportion of the particles that emanate from the sample or the work region and pass through the first clearance do not pass through the second clearance but are instead incident on the detection area of the second detector and hence rendered detectable. Compared to the case without an auxiliary lens, the particle beam microscope therefore enables an improved detection of backscattered particles.

### BRIEF DESCRIPTION OF THE DRAWINGS

Embodiments of the disclosure are explained in more detail below with reference to figures, in which:

FIG. 1 shows a schematic illustration of a particle beam microscope; and

FIG. 2 shows a further schematic illustration of the particle beam microscope.

### DETAILED DESCRIPTION

### Particle Beam Microscope

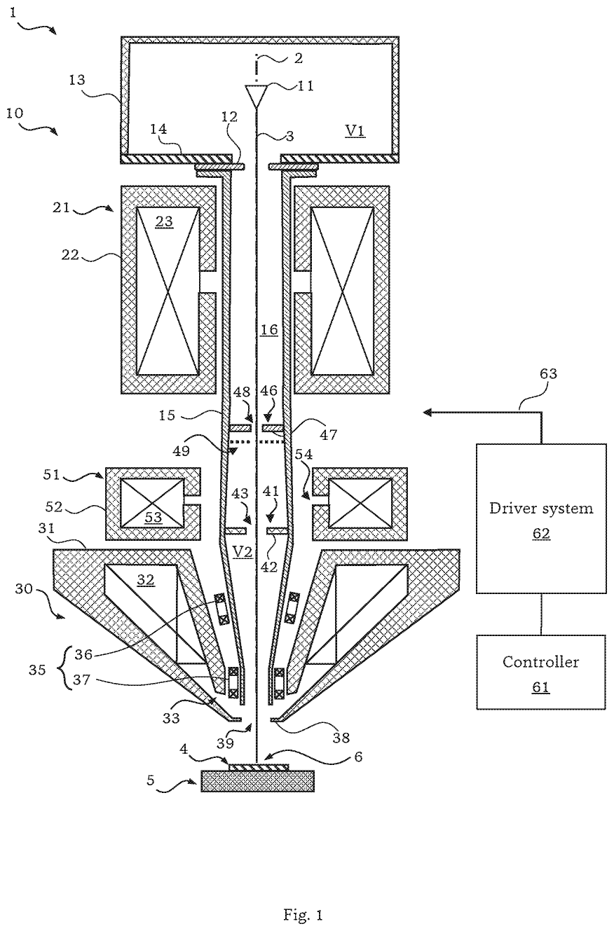

FIG. 1 shows a schematic illustration of a particle beam microscope 1. In the example shown, the particle beam microscope 1 is a scanning electron microscope. However, the particle beam microscope 1 may also be an ion beam column, for example a focused ion beam system. The particle beam microscope 1 can be part of a particle beam system that may have multiple such particle beam microscopes having a shared work region.

The particle beam microscope 1 comprises a particle beam column 10. The particle beam column 10 comprises a particle source 11 configured to provide charged particles for an intended particle beam 3. An electric potential can be applied to the particle source 11.

The particle beam column 10 comprises an acceleration electrode 12. An electric potential can be applied to the acceleration electrode 12. The resultant voltage between the acceleration electrode 12 and the particle source 11 generates an electric field that accelerates the particles in the particle beam 3.

The particle source 11 and the acceleration electrode 12 are arranged in a first vacuum region V1 in which a first vacuum is formed during operation. For example, the first vacuum is formed by a first housing section 13, a second housing section 14, the acceleration electrode 12 and a pump, not illustrated, which evacuates the vacuum region V1. The first housing section 13 is designed for example as an electrical conductor, whereas the second housing section 14 is an electrical insulator.

The particle beam column 10 further comprises a beam tube 15 arranged downstream of the acceleration electrode 12. In the example shown in FIG. 1, the beam tube 15, viewed along a central axis 2 of the particle beam column 10, extends approximately from the acceleration electrode 12 as far as into the inside of an objective lens 30. The beam tube 15 comprises a tubular body with a hollow interior 16. During operation, the particle beam 3 that emanates from the acceleration electrode 12 passes through the interior 16 of the beam tube 15. The beam tube 15 and the acceleration electrode 12 are electrically conductively connected to each other. The electric potential of the beam tube 15 therefore equals the electric potential that is applied to the acceleration electrode 12.

During operation, the particle beam microscope 1 has, in the beam tube 15, a second vacuum region V2 in which a second vacuum, possibly different from the first vacuum in the first vacuum region V1, is formed. For example, the second vacuum region V2 is formed by the beam tube 15, the acceleration electrode 12 and a pump, not illustrated, which evacuates the vacuum region V2. The acceleration electrode 12 is located at an interface between the two vacuum regions V1 and V2 and serves as a pressure stage stop. The particle beam 3 passes through the interface of the two vacuum regions V1 and V2.

The particle beam column 10 further comprises a condenser lens 21 configured to generate a magnetic field. Alternatively, the condenser lens 21 can be configured to generate an electric field. The magnetic or electric field generated by the condenser lens 21 serves to focus the particle beam 3 between the acceleration electrode 12 and a second detection area 47 (described in detail later). In the present case, an embodiment in which the condenser lens 21 is in the form of a magnetic lens and generates a magnetic field is described by way of example. The condenser lens 21 comprises a magnetic core 22 for guiding the magnetic field and an excitation coil 23 for generating the magnetic field. The magnetic core 22 is designed to be substantially rotationally symmetric about the central axis 2. By way of example, the magnetic core 22 is embodied in one piece. The magnetic core 22 is arranged completely outside the beam tube 15. The magnetic core 22 is arranged downstream of the acceleration electrode 12 along the central axis 2. By focusing the particle beam 3 upstream of the objective lens 30, the condenser lens 21 changes the divergence angle of the particle beam 3. This allows the beam diameter of the particle beam 3 to be varied. For example, the beam diameter of the particle beam 3 may be adapted to the effective range of the objective lens 30.

The condenser lens 21 is designed such that a location of maximum strength of the magnetic field of the condenser lens 21 is arranged between the second detection area 47 and the acceleration electrode 12.

The particle beam column 10 furthermore comprises the objective lens 30, which is arranged downstream of the acceleration electrode 12 and downstream of the condenser lens 21. The objective lens 30 is configured to focus the particle beam 3 on a work region 6. A sample 4 can be arranged in the work region 6, for example on a sample holder 5. The work region 6 is situated outside the particle beam column 10. Although not shown in FIG. 1, the particle beam microscope 1 comprises a vacuum chamber into which the particle beam 3 enters and in which the work region 6 is arranged.

For example, the objective lens 30 comprises a magnetic core 31 and an excitation coil 32. The excitation coil 32 is configured to generate a magnetic field that is guided by the magnetic core 31. The magnetic field leaves the magnetic core 31 from a gap 33 in the magnetic core 31 and is formed, when excited appropriately, such that the magnetic field has a focusing effect on the particle beam 3.

The particle beam column 10 further comprises a deflection system 35. The deflection system 35 is arranged along the central axis 2 and level with the objective lens 30. The deflection system 35 is configured to deflect the particle beam 3 in the radial direction (i.e. transversely to the central axis 2), in order thereby to direct the particle beam 3 to different locations in the work region 6 and hence to different locations on the surface of the sample 4. The deflection system 35, in the example shown in FIG. 1, comprises two deflection units 36 and 37, which are formed from coils. In the example shown in FIG. 1, the coils of the deflection units 36 and 37 are arranged between the beam tube 15 and the magnetic core 31 of the objective lens 30. The two deflection units 36 and 37 are arranged in a manner distributed along the central axis 2.

The particle beam column 10 furthermore comprises an end aperture 38 that is arranged downstream of the beam tube 15 and has an opening 39, through which the particle beam 3 passes and enters the vacuum chamber. An electric potential can be applied to the end aperture 38. The electric potential of the end aperture 38 and the electric potential of the beam tube 15 are generated such that the resultant voltage generates an electric field that influences the particle beam 3 between the end aperture 38 and the beam tube 15. For example, the electric field extends substantially parallel to the central axis 2. The direction and the strength of the electric field can be set variably on the basis of the voltage between the beam tube 15 and the end aperture 38. For example, the voltage between the beam tube 15 and the end aperture 38 is set such that the particles in the particle beam 3 are decelerated. This allows the landing energy of the particles in the particle beam 3 to be set, i.e. the kinetic energy of the particles in the particle beam 3 with which the particles in the particle beam 3 are incident on the sample 4.

In the example shown in FIG. 1, the end aperture 38 is formed by the magnetic core 31. However, this is purely exemplary. The end aperture 38 may be separate and electrically insulated from the magnetic core 31.

The particle beam microscope 1 furthermore comprises the sample holder 5 on which the sample 4 is able to be positioned. An electric potential can be applied to the sample holder 5 or the sample 4. The electric potential of the end aperture 38 and the electric potential of the sample 4 or sample holder 5 are generated such that a resultant voltage generates an electric field that influences the particle beam 3 between the end aperture 38 and the sample 4 or sample holder 5. For example, the electric field extends substantially parallel to the central axis 2. For example, the voltage between the end aperture 38 and the sample 4 or the sample holder 5 is set such that the particles in the particle beam 3 are decelerated. This allows the landing energy of the particles in the particle beam 3 to be set.

The particle beam column 10 furthermore comprises a first detector 41 configured to output a first detection signal based on particles that are incident on a first detection area 42. The first detection area 42 is arranged within the particle beam column 10, for example within the beam tube 15. The first detection area 42 is arranged between the acceleration electrode 12 and the objective lens 30. This means that the first detection area 42 is arranged along the central axis 2 of the particle beam column 10 between the acceleration electrode 12 and a location of maximum strength of the field generated by the objective lens 30. The first detection area 42 at least partially surrounds (i.e. partially or completely surrounds) a clearance 43 through which the particle beam 3 passes when the particle beam column 10 is in operation. The first detection area 42 surrounds the clearance 43 (in part or in full) in a circumferential direction about the central axis 2. For example, the clearance 43 is formed by an opening in the first detection area 42 that extends through the first detection area 42. Alternatively, the first detection area 42 may have e.g. a split by way of a gap that extends through the first detection area 42 along the central axis 2. The first detection area 42 can face the work region 6.

The first detection area 42 may comprise multiple partial detection areas which jointly surround the clearance 43 at least in part. The partial detection areas may each generate a detection signal.

As shown in FIG. 1 by way of example, the first detector 41 may be arranged fully within the particle beam column 10. For this purpose, the first detector 41 may be in the form of a semiconductor detector, which is configured to detect electrically charged particles.

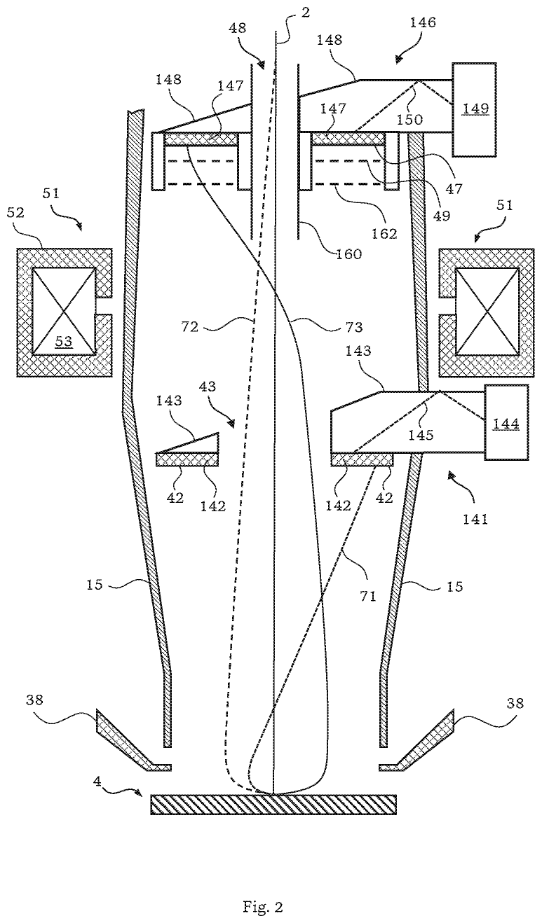

FIG. 2 shows a schematic illustration of a part of the particle beam column 10 in which the first detector 41 has been replaced by a first detector 141. The first detector 141 comprises a scintillator 142, a light guide 143 and a light detector 144. The first detection area 42 of the first detector 141 is provided on a surface of the scintillator 142. The scintillator 142 emits light 145 in response to the incidence of charged particles. The light 145 emitted by the scintillator 142 propagates through the light guide 143, which extends from the interior 16 through the beam tube 15 to outside the particle beam column 10. The light detector 144 is connected to the light guide 143 and detects the light 145. The detection signal of the first detector 141 is generated by the light detector 144.

Particles (interaction products) 71, 72, 73, which are illustrated schematically in FIG. 2, are emitted from the sample 4 as a result of interaction between the particle beam 3 and the sample 4. The particles 71, 72, 73 emitted by the sample 4 or emanating from the work region 6 pass into the beam tube 15 through the end aperture 38 and, depending on their trajectory, impinge on the first detection area 42 or pass through the first clearance 43. In the example shown in FIG. 2, the particle 71 impinges on the first detection area 42, and the particles 72 and 73 pass through the first clearance 43.

The detection signal of the first detector 41, 141 is transmitted to a controller 61 by a signal line (not depicted in the figures).

Returning to FIG. 1, the particle beam column 10 furthermore comprises a second detector 46 configured to output a second detection signal based on particles that are incident on the second detection area 47. The second detection area 47 is arranged within the particle beam column 10, for example within the beam tube 15. The second detection area 47 is arranged between the acceleration electrode 12 and the first detection area 42. This means that the second detection area 47 is arranged along the central axis 2 of the particle beam column 10 between the acceleration electrode 12 and the first detection area 42. The second detection area 47 at least partially surrounds (i.e. partially or completely surrounds) a clearance 48 through which the particle beam 3 passes when the particle beam column 10 is in operation. The second detection area 47 surrounds the clearance 48 (in part or in full) in the circumferential direction about the central axis 2. For example, the clearance 48 is formed by an opening in the second detection area 47 that extends through the second detection area 47. Alternatively, the second detection area 47 may have e.g. a split by way of a gap that extends through the second detection area 47 along the central axis 2. The second detection area 47 can face the work region 6.

The second detection area 47 may comprise multiple partial detection areas which jointly surround the clearance 48 at least in part. The partial detection areas may each generate a detection signal.

As shown in FIG. 1 by way of example, the second detector 46 may be arranged fully within the particle beam column 10.

FIG. 2 shows an example in which the second detector 46 has been replaced by a second detector 146. The second detector 146 comprises a scintillator 147, a light guide 148 and a light detector 149. The second detection area 47 of the second detector 146 is provided on a surface of the scintillator 147. The scintillator 147 emits light 150 in response to the incidence of charged particles. The light 150 emitted by the scintillator 147 propagates through the light guide 148, which extends from the interior 16 through the beam tube 15 to outside the particle beam column 10. The light detector 149 is connected to the light guide 148 and detects the light 150. The detection signal of the second detector 146 is generated by the light detector 149.

The particles emitted by the sample 4 or emanating from the work region 6 and passing through the first clearance 43 impinge on the second detection area 47 or pass through the second clearance 48, depending on their trajectory.

The detection signal of the second detector 46, 146 is transmitted to the controller 61 by a signal line (not depicted in the figures).

The particle beam column 10 furthermore comprises a grid electrode 49 arranged between the first detection area 42 and the second detection area 47. The grid electrode 49 differs from the auxiliary lens. An electric potential can be applied to the grid electrode 49. The grid electrode 49 is illustrated in a much simplified manner in FIG. 1. A more detailed configuration of the grid electrode 49 is illustrated in FIG. 2. As shown in FIG. 2, a tubular shield 160 is arranged within the beam tube 15. During operation, the particle beam 3 passes through the interior of the shield 160. The shield prevents the electric potential applied to the grid electrode from being influenced and thereby avoids electric fields that could influence the particle beam 3. Moreover, a further grid electrode 162 is provided to assist the shielding effect. An electric potential can be applied to the scintillator 147, the shield 160 and the further grid electrode 162. For example, the electric potential of the beam tube 15 is applied to the scintillator 147, the shield 160 and the further grid electrode 162.

As shown in FIGS. 1 and 2, the particle beam column 10 furthermore comprises an auxiliary lens 51 configured to generate a magnetic field for focusing particles 72, 73 emanating from the work region 6 and passing through the first clearance 43. For example, the auxiliary lens 51 comprises a magnetic core 52 and an excitation coil 53. The excitation coil 53 is configured to generate the magnetic field that is guided by the magnetic core 52. The magnetic field leaves the magnetic core 52 from a gap 54 in the magnetic core 52 and is formed, when excited appropriately, such that the magnetic field has a focusing effect on particles emitted by the sample 4 or emanating from the work region 6 and passing through the first clearance 43.

In an alternative to the generation of a magnetic field or in addition, the auxiliary lens 51 may be configured to generate an electric field (for example an electrostatic field), which has a focusing or defocusing effect on the particles emitted by the sample 4 or emanating from the work region 6 and passing through the first clearance 43.

The auxiliary lens 51 may be configured such that a location of maximum strength of the field generated by the auxiliary lens 51 is arranged between the objective lens 30 and the first detection area 42. However, the location of maximum strength of the field generated by the auxiliary lens 51 should be arranged relatively close to the first detection area 42 in this case.

Alternatively, the auxiliary lens 51 may be configured such that the location of maximum strength of the field generated by the auxiliary lens 51 is arranged in the clearance 43.

Further alternatively, the auxiliary lens 51 may be configured such that the location of maximum strength of the field generated by the auxiliary lens 51 is arranged between the first detection area 42 and the second detection area 47. An example of this configuration is depicted in FIG. 1.

The particle beam microscope 1 furthermore comprises a driver system 62. The driver system 62 is configured to generate the electric potentials, voltages and currents used to operate the particle beam microscope 1 and to supply them to the components of the particle beam microscope 1 and of the sample 4. For example, the driver system 62 generates the electric potential for the particle source 11, the acceleration electrode 12, the beam tube 15, the end aperture 38, the grid electrode 49, the sample 4 and the sample holder 5 and the electric currents for operating the objective lens 30, the condenser lens 21 and the auxiliary lens 51.

For this purpose, the driver system 62 may comprise one or more voltage and current sources that generate the electric potentials, voltages and currents used to operate the components of the particle beam microscope 1. A line 63 represents all of the electrical lines that are used to supply the electric potentials, voltages and currents from the driver system 62 to the individual components of the particle beam microscope 1. The line 63 is illustrated only schematically.

The particle beam microscope 1 furthermore comprises the controller 61 for controlling the particle beam microscope 1. The controller 61 controls the particle beam column 10, for example, by controlling the driver system 62. The controller 61 may thereby set the individual electric potentials, voltages and currents used to operate the components of the particle beam microscope 1 in a targeted manner and thus control the operation and effects of the components of the particle beam microscope 1. The electric potentials, voltages and currents that should be generated by the driver system 62 may be represented in the controller 61 by corresponding operating parameters. For example, a value of an operating parameter defines a value of an electric potential, of a voltage or of an electric current.

The controller 61 can modify the functioning and effect of a component of the particle beam microscope 1 by virtue of changing the value of the corresponding operating parameter. The values of the operating parameters may be stored in a memory of the controller 61 and be changed by a processor of the controller 61. A set of values of operating parameters that is sufficient to operate the particle beam microscope 1 defines a mode of operation of the particle beam microscope 1. Multiple sets of values of operating parameters that define multiple different modes of operation may be stored in the memory of the controller 61. The controller 61 may accordingly operate the particle beam microscope 1 selectively in one of multiple modes of operation. For this purpose, the controller 61 loads the values of the operating parameters of the selected mode of operation from the memory and instructs the driver system 62 to generate the electric potentials, voltages and currents used to operate the components of the particle beam device 1 in accordance with the loaded values of the operating parameters. A user may use a user interface to change the values of the operating parameters of a mode of operation. Various exemplary modes of operation are described below.

### Modes of Operation

The controller 61 may be configured to operate the particle beam column 10 in a first mode of operation. In the first mode of operation, the particle beam 3 is directed to the work region 6 and the auxiliary lens 51 is switched on. This means that the auxiliary line 51 generates an electric and/or magnetic field. In the first mode of operation, the auxiliary lens 51 brings about improved detection of particles which emanate from the work region 6 and pass through the first clearance 43, by virtue of the particles being deflected by the focusing effect of the magnetic auxiliary lens 51 such that the particles do not pass through the second clearance 48 but impinge on the second detection area 47.

The controller 61 may be configured to operate the particle beam column 10 in a second mode of operation. In the second mode of operation, the particle beam 3 is directed to the work region 6 and the auxiliary lens 51 is switched off. This means that the auxiliary line 51 does not exert a deflecting effect on particles which emanate from the work region 6 and pass through the first clearance 43. The second mode of operation corresponds to a conventional mode of operation without the auxiliary line 51.

The effect of the auxiliary lens 51 is explained by way of example with reference to FIG. 2. Reference sign 72 denotes a trajectory of a backscattered particle (interaction product) in the case of the auxiliary lens 51 being switched off (second mode of operation). The particle 72 emanates from the work region 6, passes through the first clearance 43 and is not influenced by the auxiliary lens 51 since the auxiliary lens 51 is switched off. As a result, the particle 72 passes through the effective range of the auxiliary lens 51 in a straight line and subsequently passes through the second clearance 48.

By contrast, reference sign 73 denotes a trajectory of a backscattered particle (interaction product) in the case of the auxiliary lens 51 being switched on (first mode of operation). The particles 72 and 73 are emitted from the same location of the sample 4 and have the same emission energy and same emission angle with respect to the central axis 2. However, to make FIG. 2 clearer, the trajectory of the particle 72 has been depicted mirrored about the central axis 2. The particle 73 emanates from the work region 6, passes through the first clearance 43 and is influenced (focused/deflected) by the auxiliary lens 51 since the auxiliary lens 51 is switched on. As a result, the particle 72 changes direction within the effective range of the auxiliary lens 51 and subsequently impinges on the second detection area 47.

The auxiliary lens 51 causes the number of particles per unit time that pass through the first clearance 43 and are incident on the second detection area 47 in the first mode of operation to be greater than the number of particles per unit time that pass through the first clearance 43 and are incident on the second detection area 47 in the second mode of operation. This improves the detection efficiency of particles that emanate from the work region 6 and pass through the first clearance 43.

So that the auxiliary lens 51 can provide a suitable effect, the distance between the first detection area 42 and the second detection area 47 should be suitably chosen, and the auxiliary lens 51 should also be excited to a sufficient extent. According to a configuration, the distance between the first detection area 42 and the second detection area 47 is at least 80 mm.

In the first mode of operation, the auxiliary lens 51 causes the particle beam 3 to have an additional cross-over in comparison with the second mode of operation. The term cross-over denotes a focal region of the particle beam within the particle beam column 10. In other words, the term cross-over denotes a region on the central axis 2 in which the trajectories of different particles in the particle beam 3 intersect.

According to a first special configuration of the first mode of operation (“secondary particle detection mode”), the controller 61 can be configured to operate the particle beam microscope 1 in the first mode of operation such that a magnitude of the landing energy of the particles from the particle beam 3 is less than 5 keV, for example less than 2 keV. Accordingly, the particles from the particle beam 3 are incident on the sample 4 with a relatively low landing energy. In the secondary particle detection mode, the first detector 42 predominantly detects secondary particles, but some of the generated secondary particles pass through the first clearance 43. The secondary particles passing through the first clearance 43 are focused by the switched-on magnetic auxiliary lens 51 and subsequently predominantly incident on the second detection area 47. The first detection signal and the second detection signal are therefore based on detections of secondary particles.

According to a second special configuration of the first mode of operation (“backscattered particle detection mode”), the controller 61 can be configured to operate the grid electrode 49 in the first mode of operation such that particles whose emission energy is less than an adjustable first threshold value are unable to pass the grid electrode 49. In other words, the controller 61 can be configured to operate the grid electrode 49 such that only particles whose emission energy is greater than the adjustable first threshold value or equals the adjustable first threshold value are capable of passing the grid electrode 49.

For example, the electric potential applied to the grid electrode 49 is set such that secondary particles with a relatively low emission energy are unable to pass the grid electrode 49. In this case, only those particles which pass through the first clearance 43 and have an emission energy greater than the adjustable first threshold value pass the grid electrode 49 and can be detected by the second detector 46. In this way, it is possible to detect substantially only backscattered particles using the second detector 46. For example, the electric potential applied to the grid electrode 49 is set such that the threshold value is defined as a value obtained by subtracting a tolerance value from the landing energy, with the tolerance value for example being 20% of the landing energy or 10% of the landing energy. For example, the controller 61 operates the particle beam column 10 such that the landing energy is 1 keV, and the grid electrode 49 only allows particles having an emission energy of at least 900 eV to pass. In this way, substantially only backscattered particles are detected using the second detector 46.

According to a third special configuration of the first mode of operation (“filter mode”), the controller 61 can be configured to operate the auxiliary lens 51 in the first mode of operation such that particles that emanate from the work region 6 and pass through the first clearance 43 and have an emission energy that is less than the landing energy of the particles in the particle beam 3 by at least an adjustable second threshold value are directed to the second detection area. For example, the controller 61 operates the particle beam column 10 such that the landing energy is 1 keV. In this example, the controller 61 operates the auxiliary lens 51 for example such that the auxiliary lens 51 substantially only directs those particles to the second detection area 47 that emanate from the work region 6 and pass through the first clearance 43 with an emission energy of no more than 900 eV (corresponding to a value at least 100 eV less than the landing energy of 1 keV). This corresponds to a second threshold value of 100 eV. By contrast, particles that emanate from the work region 6 and pass through the first clearance 43 with an emission energy of at least 900 eV are not directed to the second detection area 47 but pass through the second clearance 48 despite the effect of the auxiliary lens 51. This realizes an energy filter with regard to the emission energy of particles which are detectable by the second detector 46.

The controller 61 may be configured to operate the particle beam column 10 in a third mode of operation. In the third mode of operation, the controller 61 controls the condenser lens 21 and the auxiliary lens 51 interdependently. As a result, the condenser lens 21 and the auxiliary lens 51 form a condenser system which is controlled by the controller 61 as a unit.

What is claimed is:

1. A particle beam microscope, comprising:
a particle beam column, comprising:
a particle source configured to provide charged particles of a particle beam;
an acceleration electrode configured to accelerate the particles in the particle beam;
an objective lens configured to focus the particle beam on a work region outside the particle beam column;
a first detector configured to output a first detection signal based on particles incident on a first detection area, the first detection area being within the particle beam column between the acceleration electrode and the objective lens, and the first detection area at least partially surrounding a first clearance traversed by the particle beam when the particle beam column is in operation;
a second detector configured to output a second detection signal based on particles incident on a second detection area, the second detection area being within the particle beam column between the acceleration electrode and the first detection area, and the second detection area at least partially surrounding a second clearance traversed by the particle beam when the particle beam column is in operation; and
an auxiliary lens configured to generate a magnetic field to focus particles that emanate from the work region and pass through the first clearance.

2. The particle beam microscope of claim 1, further comprising a controller configured to operate the particle beam column in a first mode of operation in which the particle beam is directed to the work region and the auxiliary lens is on.

3. The particle beam microscope of claim 2, wherein the controller is configured to operate the particle beam column in a second mode of operation in which the particle beam is directed to the work region and the auxiliary lens is off.

4. The particle beam microscope of claim 2, wherein the auxiliary lens is configured to cause a number of particles per unit time that pass through the first clearance and that are incident on the second detection area in the first mode of operation to be greater than a number of particles per unit time that pass through the first clearance and that are incident on the second detection area in the second mode of operation.

5. The particle beam microscope of claim 4, wherein, in the first mode of operation, the auxiliary lens causes the particle beam to have an additional cross-over in comparison with the second mode of operation.

6. The particle beam microscope of claim 3, wherein, in the first mode of operation, the auxiliary lens causes the particle beam to have an additional cross-over in comparison with the second mode of operation.

7. The particle beam microscope of claim 2, wherein the controller is configured to operate the particle beam microscope in the first mode of operation so that a magnitude of a landing energy of the particles from the particle beam is less than 5 keV.

8. The particle beam microscope of claim 2, further comprising a grid electrode between the first and second detection areas, wherein the controller is configured to operate the grid electrode in the first mode of operation so that particles with an emission energy that is less than an adjustable first threshold value are unable to pass the grid electrode.

9. The particle beam microscope of claim 8, wherein the controller is configured to operate the auxiliary lens in the first mode of operation so that particles that emanate from the work region and that pass through the first clearance and have an emission energy that is less than a landing energy of the particles in the particle beam by at least an adjustable second threshold value are directed to the second detection area.

10. The particle beam microscope of claim 2, wherein the controller is configured to operate the auxiliary lens in the first mode of operation so that particles that emanate from the work region and that pass through the first clearance and have an emission energy that is less than a landing energy of the particles in the particle beam by at least an adjustable threshold value are directed to the second detection area.

11. The particle beam microscope of claim 1, wherein the first detection area faces the work region.

12. The particle beam microscope of claim 1, wherein the second detection area faces the work region.

13. The particle beam microscope of claim 1, wherein a distance between the first and second detection areas is at least 80 millimeters.

14. The particle beam microscope of claim 1, wherein the particle beam microscope is configured so that, during operation of the particle beam microscope, a location of maximum strength of the field generated by the auxiliary lens is: i) between the objective lens and the first detection area; ii) in the first clearance; or iii) between the first and second detection areas.

15. The particle beam microscope of claim 1, further comprising a condenser lens configured to generate a magnetic field, wherein the condenser lens is configured so that, during operation of the particle beam microscope, a location of maximum strength of the magnetic field of the condenser lens is between the second detection area and the acceleration electrode.

16. The particle beam microscope of claim 15, further comprising a controller configured to operate the condenser lens and the auxiliary lens interdependently as a condenser system.

17. The particle beam microscope of claim 16, wherein the controller is configured to operate the particle beam column in a first mode of operation in which the particle beam is directed to the work region and the auxiliary lens is on.

18. The particle beam microscope of claim 1, further comprising a controller configured to operate the particle beam column in a first mode of operation in which the particle beam is directed to the work region and the auxiliary lens is on, wherein:
the controller is configured to operate the particle beam column in a second mode of operation in which the particle beam is directed to the work region and the auxiliary lens is off; and
the auxiliary lens is configured to cause a number of particles per unit time that pass through the first clearance and that are incident on the second detection area in the first mode of operation to be greater than a number of particles per unit time that pass through the first clearance and that are incident on the second detection area in the second mode of operation.

19. The particle beam microscope of claim 1, further comprising a controller configured to operate the particle beam column in a first mode of operation in which the particle beam is directed to the work region and the auxiliary lens is on, wherein the controller is configured to operate the particle beam column:
in a second mode of operation in which the particle beam is directed to the work region and the auxiliary lens is off; and
in the first mode of operation so that a magnitude of a landing energy of the particles from the particle beam is less than 5 keV.

20. The particle beam microscope of claim 1, further comprising:
a controller configured to operate the particle beam column in a first mode of operation in which the particle beam is directed to the work region and the auxiliary lens is on; and
a grid electrode between the first and second detection areas, wherein:
the controller is configured to operate the particle beam column in a second mode of operation in which the particle beam is directed to the work region and the auxiliary lens is off; and
the controller is configured to operate the grid electrode in the first mode of operation so that particles with an emission energy that is less than an adjustable first threshold value are unable to pass the grid electrode.
